(19) United States
(12) Patent Application Publication
(10) Pub. No.: US 2007/0210297 A1
(43) Pub. Date: Sep. 13, 2007

(54) Electrical structure with a solid state electrolyte layer, memory with a memory cell and method for fabricating the electrical structure

(76) Inventor: Ralf Symanczyk, Tuntenhausen (DE)

Correspondence Address: PATTERSON & SHERIDAN, LLP;Gero McClellan / Infineon / Qimonda, 3040 POST OAK BLVD.,, SUITE 1500, HOUSTON, TX, 77056, US

(21) Appl. No.: 11/374,479

(22) Filed: Mar. 13, 2006

(51) Int. Cl. H01L 29/02; H01L 47/00

(52) U.S. Cl. 257/2

(57) ABSTRACT

The invention refers to a memory, a method of fabricating an electrical structure, and an electrical structure containing a substrate, a solid state electrolyte layer, and an electrode layer. The electrical structure contains a layer region arranged at an interface between the solid state electrolyte layer and the electrode layer. The layer region has a higher oxygen concentration than the solid state electrolyte layer and the electrode layer.

### BACKGROUND OF THE INVENTION

1. Field of the Invention

Embodiments of the present invention refer to an electrical structure, a memory with a memory cell comprising a programmable structure, a method of fabricating an electrical structure on a substrate, and a method for fabricating memory on a substrate.

2. Description of the Related Art

Memory cells comprising a solid electrolyte material are well known as programmable metallization memory cells (PMC memory cells). Memory devices including such PMC memory cells are known as conductive bridging random access memory devices (CBRAM). Storing of different states in a PMC memory cell is based on the development or diminishing of a conductive path in the electrolyte material between electrodes based on an applied electric field. Although the electrolyte material may typically have a high resistance, the conductive path between electrodes may be adjusted to lower resistance. Thus, the PMC memory cell may be set to different states corresponding to the resistance of the PMC memory cell. Typically, both states of the PMC memory cell are sufficiently time-stable in such a way that data may permanently be stored.

A PMC memory cell is operated by applying a positive or a negative voltage to the solid electrolyte of the PMC memory element. In order to store data within the PMC memory cell, the PMC memory cell is brought to a programmed state by applying a suitable programming voltage to the PMC memory cell which results in the development of the conductive path in the electrolyte material and therefore setting the PMC memory cell to a first state with low resistance. In order to store a second state, a PMC memory cell with high resistance, an erase voltage has to be supplied in such a manner that the resistance of the PMC memory cell changes back to a high resistance which refers to an erased state. To read from a PMC memory cell, a read voltage is applied that is lower than the programming voltage. With the read voltage, a current through the resistance of the PMC memory element is detected and associated with the lower or higher resistance state of the PMC memory cell.

### SUMMARY OF THE INVENTION

Embodiments of the present invention provide an improved electrical structure, an improved programmable structure, an improved memory, an improved method of fabricating an electrical structure on a substrate and an improved method of fabricating a memory on a substrate.

More particularly, embodiments of the invention provide an electrical structure with a solid state electrolyte layer and an electrode layer, whereby at an interface of the solid state electrolyte layer and the electrode layer a layer region is disposed with a higher concentration of oxygen than in the electrical layer and the solid state electrolyte layer.

A further aspect of the present invention refers to a programmable structure with an electrical structure, the electrical structure comprising a solid state electrolyte layer and an electrode layer disposed on the solid state electrolyte layer. At an interface of the solid state electrolyte layer and the electrode layer a layer region with an increased oxygen concentration is disposed.

A further aspect of the present invention refers to a memory with a memory cell comprising a programmable structure with an electrical structure comprising a substrate with a solid state electrolyte layer, an electrode layer on the solid state electrolyte layer and at an interface between the solid state electrolyte layer and the electrode layer a layer region with an increased concentration of oxygen is disposed.

The invention refers to a method of fabricating an electrical structure on a substrate, whereby between a first layer made of solid state electrolyte material and a second layer made of an electrode material, at an interface a layer region is generated by depositing oxygen. In the layer region an increased oxygen concentration is formed.

A further aspect of the present invention refers to a method of fabricating a memory on a substrate with the steps of processing front end of line processes, fabricating a memory cell with a solid state electrolyte layer, an electrode layer and a layer region with an increased oxygen concentration at an interface of the solid electrolyte layer and the electrode layer. Then the memory is processed with front end of line processes.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 depicts a programmable structure with a solid state electrolyte layer and an electrode layer, according to one embodiment of the invention.

FIG. 2 is a graph of current and bias voltage over the programmable structure during programming, reading and erasing operations, according to one embodiment of the invention.

FIG. 3 depicts a schematic view of a memory, according to one embodiment of the invention.

FIGS. 4 through 7 depict a method of forming a programmable electrical structure, according to one embodiment of the invention.

FIGS. 8 through 11 depict a second method of forming a programmable electrical structure, according to one embodiment of the invention.

FIGS. 12 through 15 depict a third method of forming a programmable electrical structure, according to one embodiment of the invention.

FIGS. 16 through 19 depict a fourth method of forming a programmable electrical structure, according to one embodiment of the invention.

### DETAILED DESCRIPTION OF THE PREFERRED EMBODIMENT

Embodiments of the present invention provide an electrical structure, a programmable electrical structure, a memory with a memory cell comprising a programmable structure, a method of fabricating an electrical structure on a substrate and a method of fabricating a memory with a memory cell.

The present invention may be described in terms of various functional components. It should be appreciated that such functional components may be realized by any number of hardware or structural components configured to conform the specified functions. For example, the present invention may employ various integrated components comprised of various electrical devices, in example resistors, transistors, capacitors, diodes and such like, the values of which may be suitably configured for various intended purposes. In addition, the present invention may be practiced in any integrated circuit application where an improved electrical structure is desired. Such general applications which may be appreciated by those skilled in the art in light of the present disclosure are not described in detail. Further, it should be noted that while various components may be suitably coupled or connected to other components within exemplary circuits, such connections and couplings can be realized by varied connections between components and by connections through other components and devices located in between.

The present invention generally relates to an electrical structure with a substrate, a solid state electrolyte layer, an electrode layer comprising metal, the electrode layer being disposed on the solid state electrolyte layer, whereby at an interface region of the two layers, a layer region is disposed comprising a higher oxygen concentration than in the two layers.

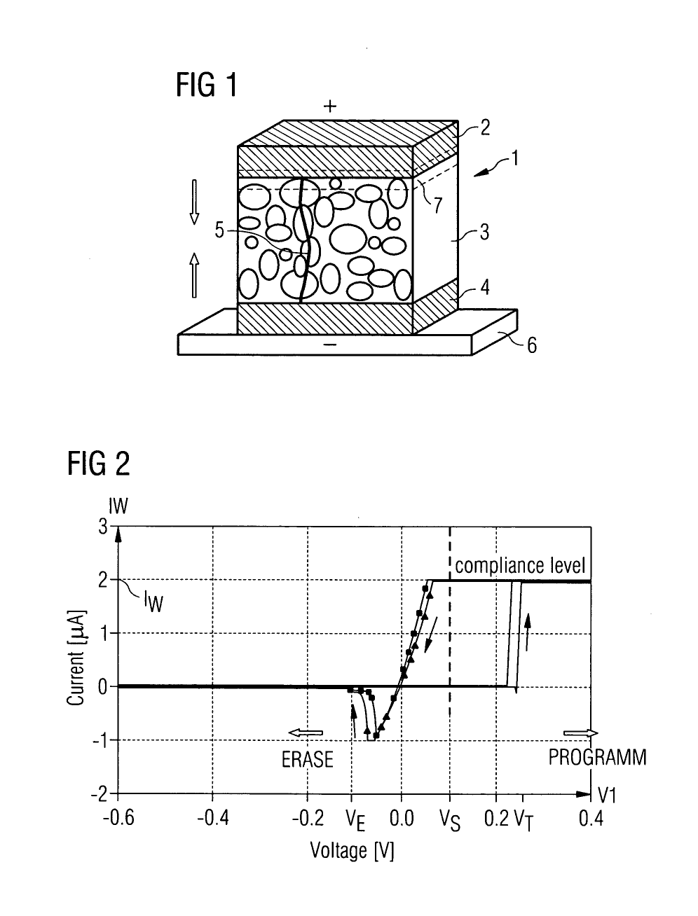

In a schematic view, FIG. 1 depicts an electrical structure 1 that is disposed on a substrate 6. The electrical structure 1 comprises a solid state electrolyte layer 3 that is covered at least partially with an electrode layer 2. The solid state electrolyte layer 3 is arranged on a second contact layer 4. The second contact layer 4 is arranged on the substrate 6. The substrate 6 may consist of a semiconductor material for example silicon or gallium arsenide. Depending on the embodiment, other materials may be used for the substrate 6. The electrode layer 2 may be connected to a high potential and the second contact layer 4 may be connected to a ground potential, in order to program the electrical structure 1 to a predetermined electrical state.

The electrical structure 1 shown in FIG. 1 may be used to store information and thus may be used in memories. For example, the electrical structure 1 may be used, in accordance with the present invention, within memory devices. For example, within a DRAM, SRAM, PROM, EEPROM, flash memory or in any combination of such memories. In addition, the electrical structure of the present invention may be used for other applications where programming or changing of electrical properties of a portion of an electrical structure are desired.

The solid state electrolyte layer 3 is formed by a material that conducts ions upon application of a sufficient voltage. Suitable materials for ion conductors include polymers, glasses and semiconductor materials. In one exemplary embodiment of the invention, the solid state electrolyte layer 3 is formed by a chalcogenide material. A chalcogenide material may include compounds of sulfur, selenium and tellurium such as GeSe, AsS, GeAsTe, AlGeAsTe, GeTeSb among others in various compositions. The solid state electrolyte layer 3 may also suitably include dissolved and/or dispersed conductive material. For example, the solid state electrolyte layer 3 may comprise a solid solution that includes dissolved metals and/or metal ions. The chalcogenide materials including silver, copper, combinations of these materials, or similar materials could be used for the solid state electrolyte layer 3.

The electrode layer 2 and the second electrode layer 4 may be formed by any suitable conductive material. For example, the electrode layer 2 and the second electrode layer 4 may be formed by doped polysilicon material or metal. In accordance with one exemplary embodiment of the present invention, one of the electrode layers, particular in this example the electrode layer 2 is formed by a material including a metal that dissolves in ion conductors when sufficient bias is applied across the electrode 2 and the second electrode layer 4. In this example the second electrode 4 is made of material that is relatively inert and does not dissolve by applying a bias voltage on the electrical structure 1. The electrode layer 2 may function as an anode during a write operation and be comprised of a material including silver that dissolves in the electrolyte layer. Depending on the embodiment, the electrode layer 2 may comprise copper. The second electrode 4 may be a cathode during the write operation and be comprised of an inert material such as tungsten, nickel, molybdenum, platinum, metal silicides, or similar materials.

Depending on the embodiment of the electrical structure, the solid state electrolyte layer 3 may at least comprise a chalcogenide material. For example, the electrolyte layer may comprise selenium and germanium. In a further embodiment, the electrolyte layer may comprise sulfur and germanium.

In one embodiment an interface region, layer region 7, may exist. The layer region 7 may contain a higher oxygen concentration compared to the solid state electrolyte layer 3 and the electrode layer 2.

The layer region 7 may reside within the solid state electrolyte layer 3 or in the electrode layer 2. In a further embodiment, the layer region 7 may be reside within both the solid state electrolyte layer 3 and the electrode layer 2. The layer region 7 is at least adjacent to the interface of the solid state electrolyte layer and the electrode layer. The layer region 7 comprises an oxygen concentration that is at least 10% higher than in the solid state electrolyte layer 3 outside of the layer region 7 and in the electrode layer 2 outside the layer region.

In a further embodiment, the oxygen concentration in the layer region 7 is 5% higher than outside the layer region 7 in the solid state electrolyte layer 3 and outside the layer region 7 in the electrode layer 2.

The higher oxygen concentration of layer region 7 improves the thermal stability of the interface between the solid state electrolyte layer 3 and the electrode layer 2. The layer region 7 with the higher oxygen concentration reduces the diffusion of metal ions from the electrode layer 2 into the solid state electrolyte layer 3. Therefore, the possibility of generating a short circuit in the solid state electrolyte layer 3 is decreased. Additionally, the possibility of degrading the structure in example the lattice of the electrode layer 2 is reduced. Therefore, recrystallization may be embedded.

In the electrical structure 1 a conductive path 5 is generated when a bias larger than a threshold voltage is applied across the solid state electrolyte layer 3. The electrical properties of the electrical structure 1 are changed to a durable conductive path. If a voltage larger than the threshold voltage is applied to the electrical structure 1, conductive ions within the solid state electrolyte layer 3 start to migrate and form a region having an increased conductivity compared to the conductor at or near the more negative of either the electrode layer 2 or the second electrode layer 4. As the conductive region forms the conductive path 5, the resistance between the electrode layer 2 and the second electrode layer 4 decreases and other electrical properties may also change. If the same voltage is applied in reverse, the conductive path 5 will dissolve back into the solid state electrolyte layer 3 and the electrical structure 1 will return to a high resistance (e.g., an erased state).

The basic reaction is if a higher voltage is applied to the solid state electrolyte layer 3, a redox reaction at the second electrode layer 4 drives metal ions from the reactive electrode layer 2 into the solid state electrolyte layer 3. Therefore, within the electrolyte layer 3, metal-rich clusters are formed. The result is a conductive path 5 that occurs between the electrode layer 2 and the second electrode layer 4. If a reverse voltage is applied to the electrical structure 1, the metal-rich clusters are dissolved and the conductive path 5 is degraded.

FIG. 2 shows a graph of the voltage and the current during a program operation, a read operation and an erase operation of the electrical structure 1, whereby the programming and the erasing operation are writing operations that are used to store a data in a memory cell of a memory. Initially, it can be assumed that the electrical structure 1 is not programmed and therefore has a high resistance and a corresponding low current with an applied voltage. If a voltage is applied with a higher voltage at the electrode layer 2 and a lower voltage at the second electrode layer 4, no current flows through the electrical structure 1 until a threshold voltage V_{T}, for example 0.23 V, is applied. With the programming voltage V_{P} rising over the threshold voltage V_{T}, current starts to flow until a working current I_{W}, for example 2 μA, is achieved. This current may be determined by a programming circuit. The voltage is then reduced to 0 V, and the current falls to 0 A. The electrical structure 1 is now programmed to a state that corresponds with a lower electrical resistance between the electrode layer 2 and the second electrode layer 4.

If the programmed state of the electrical structure 1 is to be sensed or read, a sensing voltage V_{S}, that is lower than the threshold voltage V_{T}, is applied to the electrical structure 1. For example, the sensing voltage V_{S} may be about 0.1 V. Due to the sensing voltage V_{S}, a working current Iw flows through the electrical structure 1. Without the previous programming operation, no current would flow through the electrical structure 1 when a sensing voltage V_{S} is applied. To erase the program state, a lower voltage, for example a negative voltage, is applied to the electrode layer 2. This voltage may start at 0 V, and proceed to an erase voltage V_{E}, for example a negative voltage of about −0.1 V. In response to the negative voltage a negative current flows through the electrical structure 1. When the negative voltage drops below the erase voltage V_{I}, for example below −0.1 V, the current recedes to 0 A. The electrical structure 1 again has a high resistance, as it did prior to the programming operation.

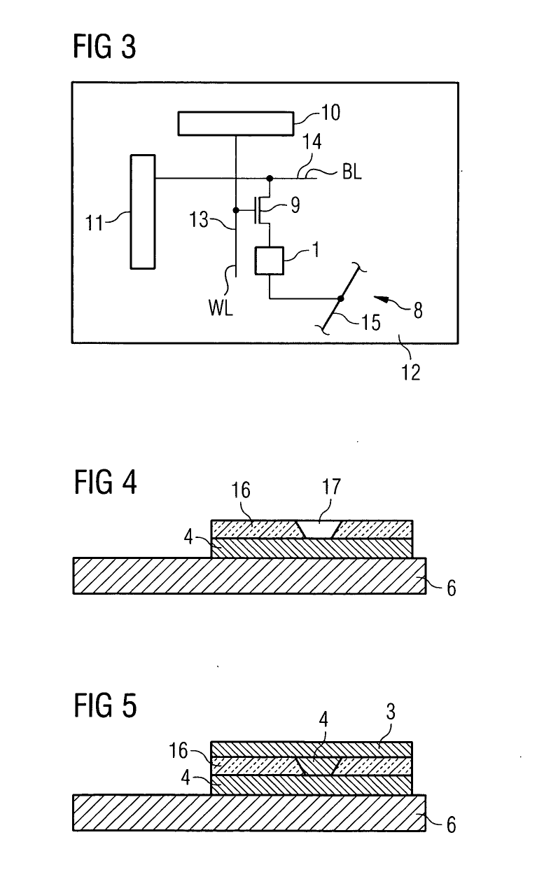

FIG. 3 depicts a schematic view of a memory 12 with a word line driver 10 and a bit line driver 11. The word line driver 10 is connected to many word lines 13 and the bit line driver 11 is connected to many bit lines 14. For simplifying reasons only one bit line 14 and one word line 13 are shown. The memory 12 comprises many memory cells 8, whereby a memory cell 8 consists of a switch 9 and an electrical structure 1. The switch 9 is arranged between the bit line 14 and the electrical structure 1 as shown in FIG. 1. A controlling input of the switch 9 is connected with the word line 13. The electrical structure 1 is arranged between the switch 9 and a plate line 15, whereby the electrode layer 2 is connected to the bit line 14 and the second electrode layer 4 is connected to the plate line 15. The plate line 15 provides a predetermined voltage level. For simplifying reasons only one memory cell 8 is depicted in FIG. 3. By controlling the word line driver 10 and the bit line driver 11 a predetermined memory cell 8 may be addressed, and depending on the voltage applied to the electrical structure 1 a program state of the electrical structure 1 is sensed or written to the electrical structure 1. A predetermined memory cell 8 is selected by applying a read voltage on the word line 13 that closes the switch 9 and connects the electrical structure 1 with the bit line 14. Depending on the voltage level that is applied on the bit line 14, the program state of the electrical structure 1 is sensed or the state of the electrical structure 1 is programmed as explained in the description of FIG. 2.

The sensed program state of the memory cell 8 refers to a program data and the data is output by output units of the memory 12. Additionally, data may be stored in the memory 12 by input units that are connected with the bit lines 14.

FIGS. 4 to 7 depict a first method for producing an electrical structure 1.

The electrical structure 1 may be a particular type of memory, i.e. a DRAM, a SRAM, a PROM, an EEPROM or a flash memory.

A memory 12 is fabricated using a substrate 6 and processing controlling units, decoder units, sensing units during a front end of line process. During the front end of line process high temperatures are generated, whereby active semiconductor elements such as transistors are formed in the substrate using layer depositing processes, ion implantations, diffusion processes and annealing processes. The substrate may be a wafer, in particular a semiconductor wafer.

FIG. 4 depicts a sectional view of a memory 12 with a substrate 6 on which a second electrode layer 4 is deposited. On the second electrode layer 4 an insulating layer 16 with a hole 17 is deposited. The insulating layer 16 is made of a dielectric material. The hole 17 is filled with the same material as the second electrode layer 4. The second electrode layer 4 is made of metal.

Next, as shown in FIG. 5, a solid state electrolyte layer 3 is deposited. The solid state electrolyte layer 3 may be made of one of the materials disclosed in the description of FIG. 1.

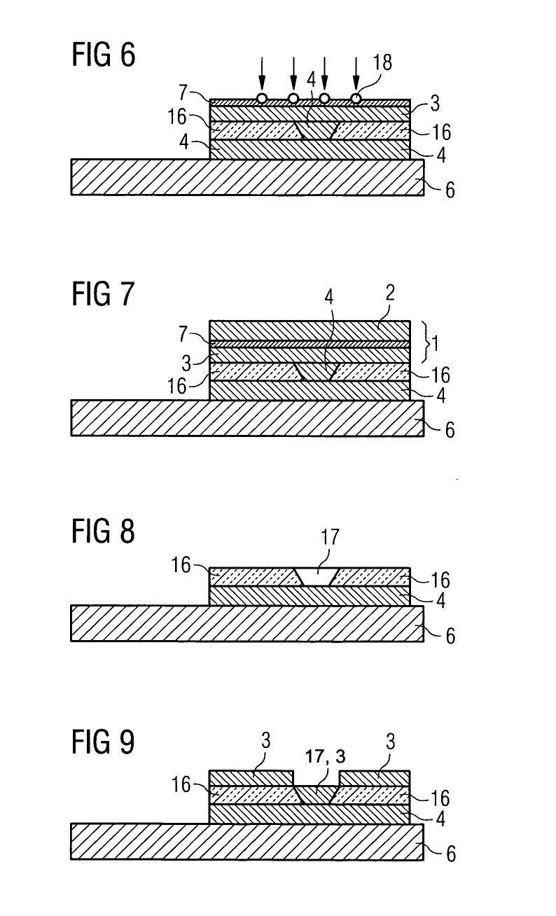

Next, an upper layer of the solid state electrolyte layer 3 is sputtered back in an oxygen atmosphere, whereby a layer region 7 is formed with an oxygen concentration 18 in an upper portion of the solid state electrolyte layer 3 as shown in FIG. 6.

Additionally, as seen in FIG. 7, an electrode layer 2 is deposited on the layer region 7. Thus an electrical structure 1 is formed with a layer region 7 at the interface between the electrode layer 2 and the solid state electrolyte layer 3.

FIG. 7 depicts an electrical structure 1 with a stud structure.

The electrical structure 1 may be processed to a memory cell and a memory, i.e. a DRAM may be produced using back end of line processes.

Depending on the embodiment, the electrical structure 1 may also be processed producing other devices, i.e. an electrical circuit.

FIGS. 8 through 11 depict a second method for producing an electrical structure 1 after a front end of line processes.

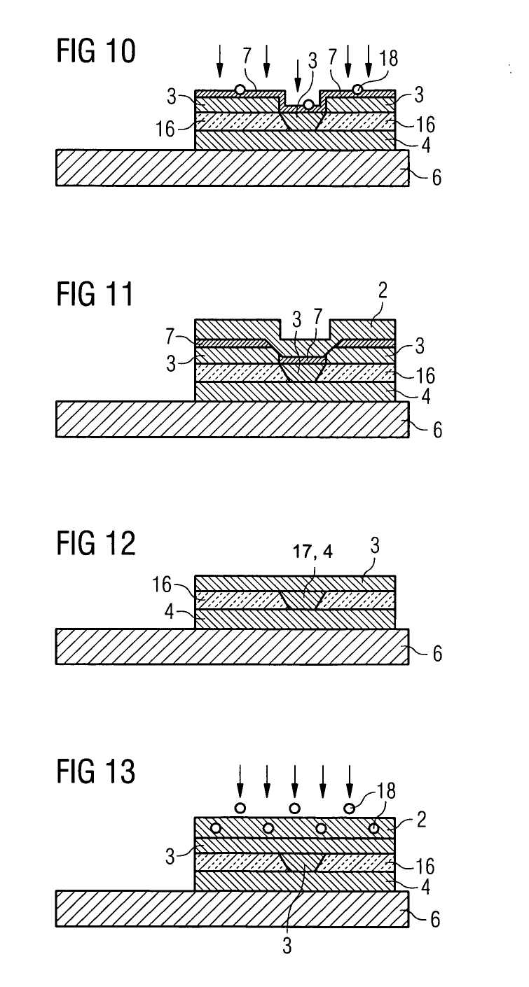

In FIG. 8 a substrate 6 is depicted that is covered with a second electrode layer 4. The second electrode layer 4 is covered with an insulating layer 16. The insulating layer 16 may be made of dielectric material. The insulating layer 16 comprises a hole 17. Next, a solid state electrolyte layer 3 is deposited on the surface of the insulating layer 16 and in the hole 17, as shown in FIG. 9. Thus the solid state electrolyte layer 3 fills up the hole 17. Next, an upper layer of the solid state electrolyte layer 3 is removed by a bias sputter process using oxygen. This generates a layer region 7 on the solid state electrolyte layer 3 comprising oxygen 18 as shown in FIG. 10. Next, the layer region 7 is covered with an electrode layer 2 as shown in FIG. 11. Thus an electrical structure 1 is formed with an active-over-via structure.

A back end of line processes may be used with the electrical structure 1 of FIG. 11 to manufacture a memory cell and a memory.

FIGS. 12 through 15 depict a third process method. FIG. 12 depicts a schematic sectional view of a substrate 6 with a second electrode layer 4. The second electrode layer 4 is covered with an insulating layer 16 comprising a hole 17. The hole 17 is filled up with material of the second electrode layer 4. On the insulating layer 16 a solid state electrolyte layer 3 is disposed. The insulating layer 16 may be made of a dielectric material. The solid state electrolyte layer 3 may be made of chalcogenide material or any other material disclosed in the description of FIG. 1.

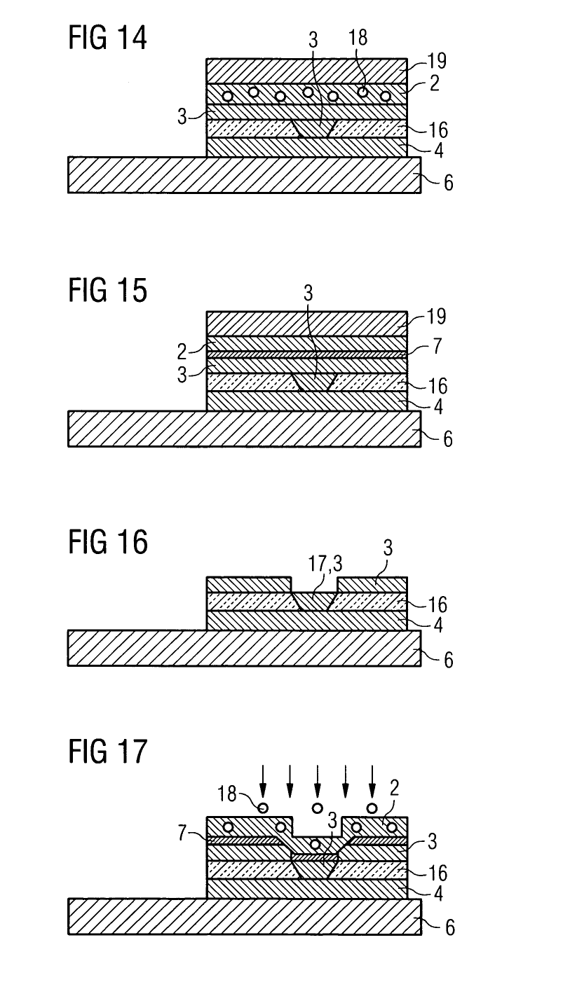

Next, as shown in FIG. 13, a second electrode layer 2 is deposited on the solid state electrolyte layer 3. During the deposition of the electrolyte layer 2 oxygen is deposited, for example by using a reactive bias sputter process. In FIG. 13 the deposition of the electrode layer 2 is schematically depicted by arrows and the oxygen 18 is schematically depicted as balls. Next, as shown in FIG. 14, a cap layer 19 is deposited on the electrode layer 2.

In a further process step, the electrical structure 1 of FIG. 14 is heated up and a layer region 7 is generated at the interface of the electrode layer 2 and the solid state electrolyte layer 3 as shown in FIG. 15. The cap layer 19 may be formed out of a dielectric material or a metal material. Therefore, according the third method it is possible to deposit the solid state electrolyte layer 3 without an oxygen ambient and to deposit the oxygen with the electrode layer 2. Performing the thermal heating process generates the layer region 7 with an increased oxygen concentration at the interface of the electrode layer 2 and the solid state electrolyte layer 3.

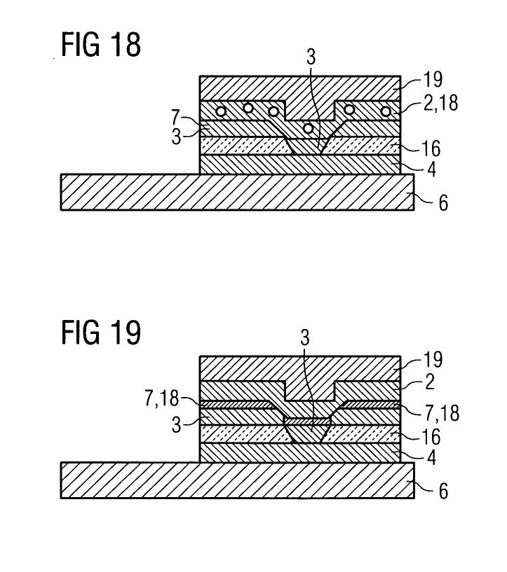

FIGS. 16 through 19 depict a fourth method for producing an electrical structure 1 on a substrate 6. FIG. 16 depicts the substrate 6 with a second electrode layer 4 that is covered by an insulating layer 16. The insulating layer 16 comprises a hole 17 that is open down to the surface of the second electrode layer 4. The insulating layer 16 is covered by a solid state electrolyte layer 3, whereby the hole 17 is filled up with the solid state electrolyte layer 3 as shown. Next in FIG. 17, an electrode layer 2 is deposited on the solid state electrolyte layer 3, whereby oxygen is deposited with the material of the electrode layer 2. The deposition may be performed by a reactive bias sputtering of the electrode layer 2 in an oxygen ambient. Therefore, the electrode layer 2 contains oxygen. Next, in FIG. 18 the electrode layer 2 is covered with a cap layer 19. The cap layer 19 may comprise dielectric material or metal material.

In a further thermal heating process, the electrical structure 1 is heated up and the oxygen generates a layer region 7 at the interface of the electrode layer 2 and the solid state electrolyte layer 3 as shown in FIG. 19. The electrical structure 1 of FIG. 19 may be used to manufacture a memory 12, whereby the electrical structure 1 is part of a memory cell 8, i.e. a DRAM.

The thickness of the layer region 7 may be enlarged by raising the partial pressure of the oxygen ambient during the bias sputtering or increasing the process time for the bias sputtering. Additionally, using the reactive sputter process for depositing the oxygen, the thickness of the region layer 7 may be enlarged by increasing the partial pressure of the oxygen during the reactive sputter process.

In a further embodiment, the memory may be produced as a conductive bridging random access memory (CBRAM) including a programmable metallization cell with the electrical structure 1. The layer region 7 may reduce the negative impact of thermal processes in particular when using a back end of line process that may use temperatures up to 400 and 450° C.

In a further embodiment, the electrode layer 2 may include copper or be made of copper.

While the foregoing is directed to embodiments of the present invention, other and further embodiments of the invention may be devised without departing from the basic scope thereof, and the scope thereof is determined by the claims that follow.

What is claimed is:

1. An electrical structure, comprising:
a substrate having formed thereon:
a first electrode layer;
a solid state electrolyte layer;
a second electrode layer; and
a region arranged at an interface of the solid state electrolyte layer and the second electrode layer, the region comprising a higher oxygen concentration than the solid state electrolyte layer and the second electrode layer.

2. The electrical structure of claim 1, wherein the solid state electrolyte layer comprises chalcogenide.

3. The electrical structure of claim 1, wherein the second electrode layer comprises a metallic material.

4. The electrical structure of claim 1, wherein the second electrode layer comprises silver.

5. The electrical structure of claim 1, wherein the second electrode layer comprises copper.

6. The electrical structure of claim 1, wherein the region is arranged in the solid state electrolyte layer.

7. The electrical structure of claim 1, wherein the region is arranged in the second electrode layer.

8. The electrical structure of claim 1, wherein the region is arranged in the solid state electrolyte layer and in the second electrode layer.

9. The electrical structure of claim 1, wherein the solid state electrolyte layer comprises selenium and germanium.

10. The electrical structure of claim 1, wherein the solid state electrolyte layer comprises sulfur and germanium.

11. The electrical structure of claim 1, wherein the solid state electrolyte layer is between the first electrode layer and the second electrode layer.

12. A memory, comprising:
at least one memory cell, the memory cell comprising:
a solid state electrolyte layer having formed thereon,
a first electrode layer;
a second electrode layer; and
a region arranged at an interface of the second electrode layer and the solid state electrolyte layer, the layer region having a higher oxygen concentration than the solid state electrolyte layer and the second electrode layer.

13. The memory of claim 12, wherein the second electrode layer comprises silver.

14. The memory of claim 12, wherein the second electrode layer comprises copper.

15. The memory of claim 12, wherein the memory is a dynamic random access memory.

16. A method for fabricating an electrical structure on a substrate, comprising:
depositing a solid electrolyte layer;
depositing an electrode layer; and
depositing oxygen at an interface region of the electrode layer and the solid state electrolyte layer.

17. The method of claim 16, wherein depositing oxygen at the interface region of the electrode layer and the solid state electrode layer comprises depositing the oxygen in the solid state electrolyte layer adjacent to the electrode layer.

18. The method of claim 17, wherein depositing the oxygen in the solid state electrolyte layer adjacent to the electrode layer comprises, partially sputtering back the solid state electrolyte layer within an oxygen-containing atmosphere.

19. The method of claim 16, wherein depositing the oxygen at the interface region of the electrode layer and the solid state electrolyte layer comprises depositing the oxygen in the electrode layer adjacent to the solid sate electrode layer.

20. The method of claim 19, wherein depositing the oxygen in the electrode layer adjacent to the solid state electrolyte layer further comprises, partially sputtering back the electrode layer within an oxygen-containing atmosphere.

21. The method of claim 19, wherein depositing the electrode layer comprises heating up an electrode material to at least 200° C.

22. The method of claim 16, further comprising covering the electrode layer with a cap layer.

23. The method of claim 16, further comprising depositing a second electrode adjacent to the solid state electrolyte layer.

24. A method of fabricating a memory, comprising:
providing a substrate having an active layer formed thereon;
fabricating a memory cell on the substrate, the memory cell comprising a first electrode, a second electrode, and a solid electrolyte layer in between the first and second electrodes; the first electrode comprising metal ions that are dissolvable in the solid electrolyte layer under an influence of a bias voltage; and
depositing oxygen to form a layer located at an interface region between the first electrode and the solid state electrolyte layer, wherein the layer contains an increased oxygen concentration compared to adjacent regions of the first electrode and the solid state electrolyte layer.
